(19) United States
(12) Patent Application Publication
(10) Pub. No.: US 2025/0377413 A1
(43) Pub. Date: Dec. 11, 2025

(54) INTELLIGENT POWER MANAGEMENT SYSTEM AND METHOD FOR MONITORING BATTERY INTEGRITY

(71) Applicant: SEMICONDUCTOR COMPONENTS INDUSTRIES, LLC, Scottsdale, AZ (US)

(72) Inventor: Hideo KONDO, Oizumi-machi (JP)

(73) Assignee: SEMICONDUCTOR COMPONENTS INDUSTRIES, LLC, Scottsdale, AZ (US)

(21) Appl. No.: 18/792,130

(22) Filed: Aug. 1, 2024

Related U.S. Application Data
(60) Provisional application No. 63/658,673, filed on Jun. 11, 2024.

(51) Int. Cl. G01R 31/392; G01R 31/367; G01R 31/3842; G01R 31/389; H02J 7/00

(52) U.S. Cl. CPC G01R 31/392; G01R 31/367; G01R 31/3842; G01R 31/389; H02J 7/0031

(57) ABSTRACT

A battery monitoring system (BMS) for a battery of a battery electric system includes a sensor array, a processor, and memory. Execution of the instructions causes the processor to receive battery parameters from the sensor array during respective charging and discharging modes of the battery, including at least a voltage, current, and temperature of the battery. Separate charge-side and discharge-side resistances of the battery are determined during charging and discharging modes, followed by calculation of a degradation level of the battery using the charge-side and discharge-side resistances. The processor may also perform a preventive action in response to the degradation level exceeding a calibrated threshold.

### CROSS-REFERENCE TO RELATED APPLICATIONS

The present application claims the benefit of priority to U.S. Provisional Application No. 63/658,673 filed on Jun. 11, 2024, which is hereby incorporated by reference in its entirety for all purposes.

### INTRODUCTION

The present disclosure relates to electrical circuit topologies and control methods for monitoring the structural integrity of batteries. Electric vehicles, standby power supplies, power stations, and other mobile and stationary battery electric systems utilize rechargeable batteries as energy storage devices. The rechargeability and high energy storage capacities of lithium-ion batteries in particular has led to widespread adoption of such batteries in a myriad of industries. For example, lithium-ion batteries are used to power electric motors in mobile and stationary battery electric systems, as well as to energize actuators, sensors, displays, and control circuits of medical devices, industrial systems, and consumer products.

While lithium-ion batteries are integral components of battery electric systems, their use comes with certain potential risks. For instance, the internal temperature of an aged or faulty battery cell can rapidly increase. Thermal management techniques such as coolant/air circulation or the use of heat sinks or cell vents are therefore used to help regulate battery temperature. However, when the temperature of a given battery cell increases beyond a point, the materials of the battery and its constituent cells can begin to melt or burn. The resulting pressure increase within the battery cell can cause the cell can or outer foil to rupture. When this happens, the cell expels high-temperature gasses, molten materials, soot, and other ejecta, which can propagate to neighboring battery cells. This condition is referred to in the art as thermal runaway, and can adversely affect operation of the battery and battery electric system as a whole.

### SUMMARY

Disclosed herein are battery monitoring systems and automated methods for monitoring a rechargeable lithium-ion or other rechargeable battery of a battery electric system. The present teachings seek to protect the battery electric system and surrounding surfaces or components from thermal damage by detecting a potentially hazardous degradation state of the battery prior to manifestation of the hazard. The present teachings thus enable issuance of an alert as an advanced warning of an impending battery failure, which in turn provides operators with sufficient time with which to perform preventive actions such as battery replacement or circuit disconnection.

The monitoring strategy as contemplated herein determines an internal resistance of the battery during two states: (1) a charging mode during which the battery is actively receiving a charging current, with the internal resistance during such a charging mode referred to below as the “charge-side resistance”, and (2) a discharging mode during which the battery provides a battery current to a connected load, with the internal resistance of the battery during such a discharging mode referred to as the “discharge-side resistance”. The two internal resistance values are then used to evaluate the present state of health (SOH) of the battery.

Above a predetermined threshold indicative of a potentially hazardous state of the battery, one or more preventive control actions may be performed to help avoid thermal damage to the battery and/or the battery electric system and its surrounding environment.

According to a representative embodiment, a battery monitoring system (BMS) includes a sensor array connectable to a battery, a processor, and a non-transitory computer-readable storage medium (“memory”). The memory includes instructions executable by the processor to cause the processor to calculate a charge-side resistance (R1) and a discharge-side resistance (R2) of the battery during the charging and discharging modes, respectively. The processor receives a voltage, a current, and a temperature of the battery from the sensor array during a charging mode of the battery and during a discharging mode of the battery. A degradation level of the battery is calculated using the charge-side resistance (R1) and the discharge-side resistance (R2). A preventive action of the battery is optionally performed in response to the degradation level exceeding a calibrated threshold.

Also disclosed herein is a method for monitoring a battery in a battery electric system. An embodiment of the method includes calculating a charge-side resistance (R1) of the battery via the EMU during the charging mode using, calculating a discharge-side resistance (R2) of the battery via the EMU during the discharging mode, and then calculating a degradation level of the battery using the charge-side resistance (R1) and the discharge-side resistance (R2). A preventive action of the battery may also be performed in response to the degradation level exceeding a calibrated threshold.

A battery electric system is also disclosed herein. An embodiment of such a system includes a battery connectable to a battery charger during a charging mode, a load connectable to the battery and energized thereby during a discharging mode, a sensor array connected to the battery, and an electronic monitoring unit (EMU). The EMU is configured to transmit a measurement request signal to the sensor array, and to receive, in response to the measurement request signal, first and second sets of battery parameters from the sensor array during the charging and discharging modes. The battery parameters include at least a voltage, a current, and a temperature of the battery.

The EMU in this implementation is configured to calculate a charge-side resistance (R1) of the battery during the charging mode using the first set of battery parameters, a discharge-side resistance (R2) of the battery during the discharging mode using the second set of battery parameters, and a degradation level of the battery using the charge-side resistance (R1) and the discharge-side resistance (R2). Thereafter, the EMU performs a preventive action of the battery in response to the degradation level exceeding a calibrated threshold.

The above summary is not intended to represent every embodiment or aspect of the present disclosure. Rather, the foregoing summary exemplifies certain novel aspects and features as set forth herein. The above noted and other features and advantages of the present disclosure will be readily apparent from the following detailed description of representative embodiments and modes for carrying out the present disclosure when taken in connection with the accompanying drawings and the appended claims.

### BRIEF DESCRIPTION OF THE DRAWINGS

The drawings described herein are for illustrative purposes only, are schematic in nature, and are intended to be exemplary rather than to limit the scope of the disclosure.

FIG. 1 illustrates a battery electric system having a rechargeable battery and a battery monitoring system (BMS) constructed in accordance with the present disclosure.

FIGS. 2A, 2B, and 2C illustrate a representative embodiment of the battery shown in FIG. 1 for various levels of capacity.

FIGS. 3A and 3B illustrate models of a representative battery in new and degraded states, respectively.

FIG. 4 is a schematic circuit diagram of the BMS of FIG. 1 in accordance with a possible embodiment.

FIG. 5 illustrates changing capacity-based cell voltages, with voltage depicted on the vertical axis and percentage state of charge (SOC)/remaining capacity depicted on the horizontal axis.

FIG. 6 illustrates state of charge (SOC)-based variations in internal resistance, with the percentage capacity or SOC shown on the horizontal axis and ohmic resistance shown on the vertical axis.

FIG. 7 is a flow chart describing a method for monitoring the battery of the battery electric system of FIG. 1.

The present disclosure may be modified or embodied in alternative forms, with representative embodiments shown in the drawings and described in detail below. Inventive aspects of the present disclosure are not limited to the disclosed embodiments. Rather, the present disclosure is intended to cover alternatives falling within the scope of the disclosure as defined by the appended claims.

### DETAILED DESCRIPTION

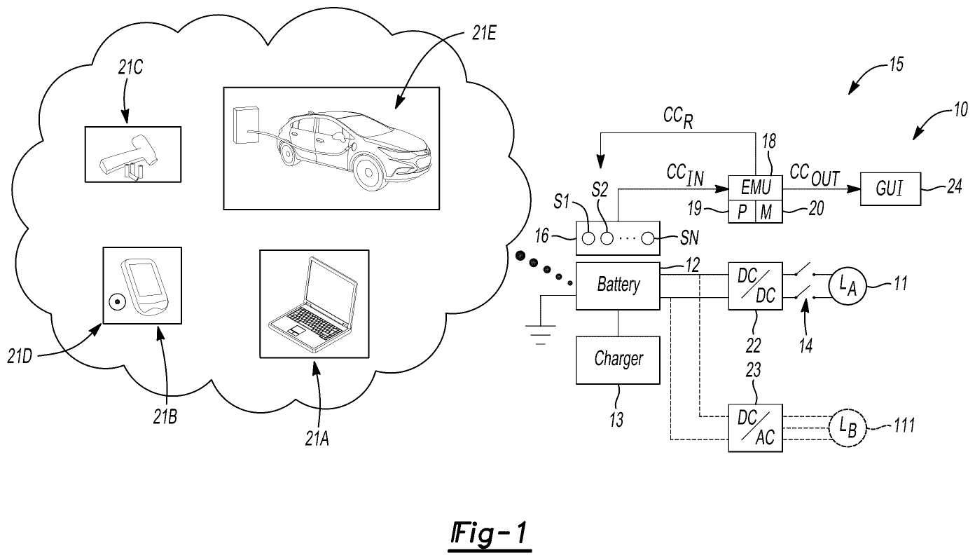

With reference to the drawings, wherein like reference numbers refer to the same or similar components throughout the several views, a battery electric system 10 is illustrated schematically in FIG. 1. The battery electric system 10 in a simplified embodiment includes a rechargeable battery 12, an electrical switch 14, a load (L_{A}) 11, and a battery monitoring system (BMS) 15. The BMS 15 in turn includes a sensor array 16 and an electronic monitoring unit (EMU) 18, with the sensor array 16 being connectable to the battery 12, for instance via hard-wired transfer conductors and/or wireless connections.

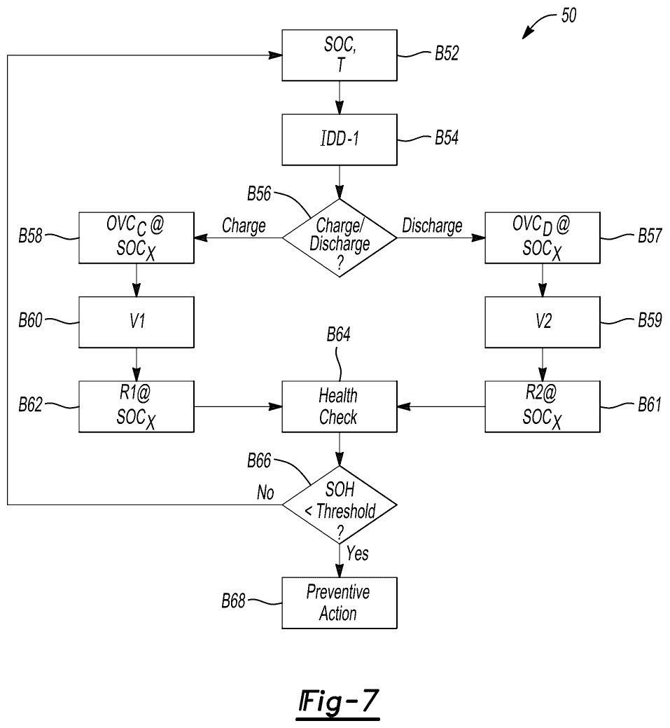

The EMU 18 as contemplated herein includes a processor (P) 19 and a non-transitory computer-readable storage medium (“memory”) (M) 20. The memory 20 includes instructions recorded thereon and executable by the processor 19 to cause the EMU 18 to perform a method 50, a non-limiting example of which is described below with reference to FIG. 7. Among other actions, the EMU 18 transmits a measurement request signal (CCR) to the sensory array 16 of the BMS 15 to initiate the present process.

The battery 12 of FIG. 1 is described hereinafter as a lithium-ion (Li) for illustrative consistency, but may be alternatively configured as another rechargeable battery in other embodiments, for instance as a lithium metal oxide (LMO), lithium metal, nickel-metal hydride (NiMH), nickel-cadmium (NiCd), or another application-specific battery chemistry. In various implementations, the battery electric system 10 can be used as part of a mobile or stationary battery-powered device. For instance as shown in FIG. 1, the battery 12 may be used to power a portable electronic device such as a computer 21A, e.g., a tablet, desktop, or laptop computer, or a cellular phone 21B.

Other applications may use the battery 12 as part of a medical device, for instance a handheld surgical tool 21C, or a wearable device 21D such as a continuous glucose monitor (CGM) as shown, or alternatively an automatic external defibrillator (AED), blood oxygen monitor, or infusion pump. Likewise, the battery 12 may be used to energize a mobile system 21E such as an electric vehicle. Still other applications may be readily envisioned, including but not limited to electronic gaming systems, control consoles, or other industrial, medical, or transportation systems. The exemplary use, chemistry, construction, and simplified depiction of the battery 12 herein is therefore illustrative of the present teachings and non-limiting thereof unless otherwise specified.

The BMS 15 of FIG. 1 may include other components in different embodiments. For example, a direct current-to-direct current (DC-DC) converter 22 may be used with the battery 12 to increase or reduce the battery voltage before energizing the load 11. A battery charger 13 may be connectable to the battery 12 to recharge the battery 12 as needed. In an alternating current (AC) configuration of the battery electric system 10, the battery 12 may be connected to a DC-to-AC inverter circuit 23, with the inverter circuit 23 operable for outputting an AC waveform to a coupled load (L_{B}) 111. The loads 11 and 111 may be variously embodied as electric motors, rotary actuators, linear actuators, displays, transducers, and/or other electrical or electromechanical devices depending on the application.

As part of the present strategy, various sensors S1, S2, . . . , SN of the sensor array 16 are used to measure or sense battery parameters during charging and discharging modes of the battery 12. The battery parameters used as part of the method 50 (FIG. 7) include at least a voltage, a current, and a temperature of the battery 12, with the EMU 18 also being configured to determine the state of charge (SOC) and an open-circuit voltage (OCV) of the battery 12 and its present charge/discharge state.

As part of the contemplated approach, input signals (CC_{IN}) from the sensor array 16 are communicated to the EMU 18. The EMU 18 thereafter outputs electronic control signals (CC_{OUT}) to a remote device 24, e.g., a graphical user interface (GUI) as shown, a display screen, and/or to the disconnect switch 14. The disconnect switch 14 may be embodied as electromechanical contactors or relays, e.g., solid state relays (SSRs), operable to disconnect the battery 12 under certain fault conditions. Although omitted from FIG. 1 for illustrative simplicity and clarity, the battery electric system 10 may be equipped with a thermal management system as summarized above to help regulate temperature of the battery 12 during its normal operation, for example cooling plates, fins, heat sinks, coolant conduit, etc. Likewise, other circuit components such as fuses may be implemented to ensure the safety and reliability of the battery electric system 10 during its operation.

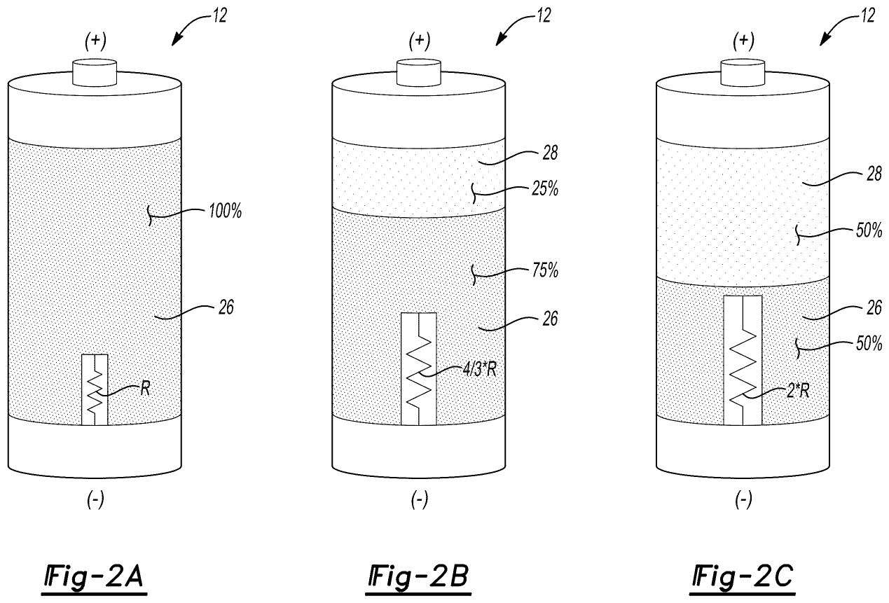

Referring now to FIGS. 2A, 2B, and 2C, which collectively illustrate the battery 12 of FIG. 1 at various levels of charge depletion, the present teachings proceed with an understanding that the internal resistance of the representative battery 12 will tend to increase over time due to age-related and other degradation. FIG. 2A depicts a new/properly functioning battery 12 having a useable nominal usable capacity 26 of 100% and an internal resistance (R). Progressive aging and deterioration of the battery 12 is illustrated in FIGS. 2B and 2C for usable capacities 26 of 75% and 50%, respectively. Relative to the new state of the battery 12 in FIG. 2A, the internal resistance of the battery 12 in FIG. 2B has increased, in this exemplary instance to (4/3)R. As age-related degradation continues, the internal resistance (R) may continue to increase, in this exemplary case to twice the level of FIG. 2A, i.e., 2R. In other words, age-related degradation of the battery 12 leads to a significant increase its internal resistance.

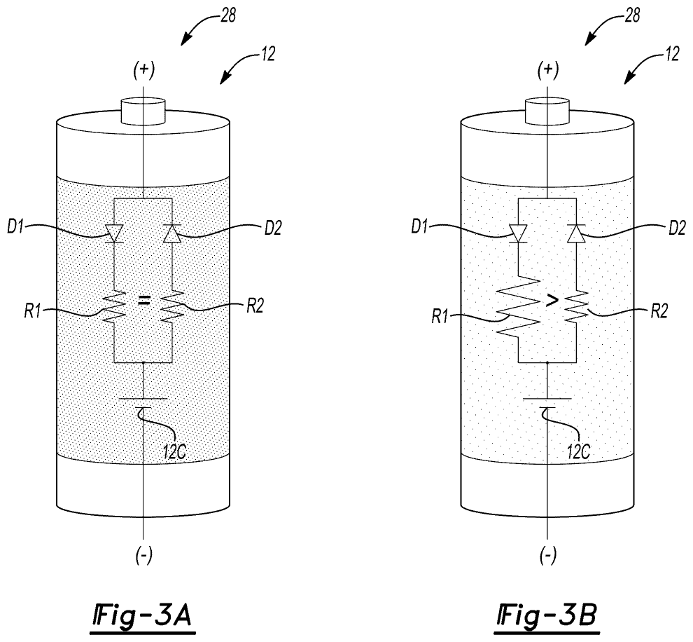

Referring briefly to FIGS. 3A and 3B, a bifurcated model 28 is used herein as part of the present strategy. That is, the internal resistance (R) of the battery 12 described above with reference to FIGS. 2A-2C is divided herein into two respective components: (1) a charge-side resistance (R1), and (2) a discharge-side resistance R2. As noted above, R1 and R2 respectively represent the internal resistance of the battery 12 as determined during charging and discharging modes of the battery 12. As shown in FIG. 3A, the charge-side and discharge-side resistances are equal for a new/properly functioning battery 12, i.e., R1=R2. The rate of increase in the internal resistance is also approximately the same for the respective charge-side and discharge-side internal resistances R1 and R2 as the battery 12 ages under normal usage conditions.

As shown in FIG. 3B, however, this “lock-step” relationship between R1 and R2 changes for a damaged battery such that the charge-side resistance (R1) exceeds the discharge-side resistance (R2), i.e., R1>R2. An ever-widening difference emerges between respective charge-side and discharge-side resistances R1 and R2 as the battery 12 continues to degrade towards a potentially hazardous state. This degradation trajectory is closely monitored by the BMS 15 of FIG. 1 as described herein, which enables the BMS 15 and its resident EMU 18 to proactively take preventive measures when protecting the battery 12, the battery electric system 10, and the surrounding environment from potential thermal damage.

R1 and R2: During a battery charging operation of a representative lithium-ion configuration of the battery 12, lithium ions migrate within the battery 12 and are absorbed onto electrode surfaces in a stable manner. However, abnormal growth and formation of unstable lithium deposits can result from repeated charging cycles or increased charging rates, e.g., during direct current fast-charging of the battery. Clusters of deposits can form elongated branch-like structures called dendrites. Dendrites and other lithium accumulations increase the charge-side resistance.

Dendrite formation in a lithium-ion battery cells is more pronounced relative to similar accumulations during discharge. While the discharge process also increases internal resistance, the accumulation of lithium deposits on the electrode surfaces during discharge modes tends to be less abnormal. The rate of increase in the discharge-side resistance (R2) is therefore lower than the increase rate of the charge-side resistance (R1). Thus, the absolute difference between the values R1 and R2, and/or their respective rates of change are monitored and tracked by the EMU 18 of FIG. 1 to ascertain the state of health (SOH) of the battery 12 and, if needed, take one or more protective or preventive actions to protect the battery 12 and/or the battery electric system 10 from thermal damage.

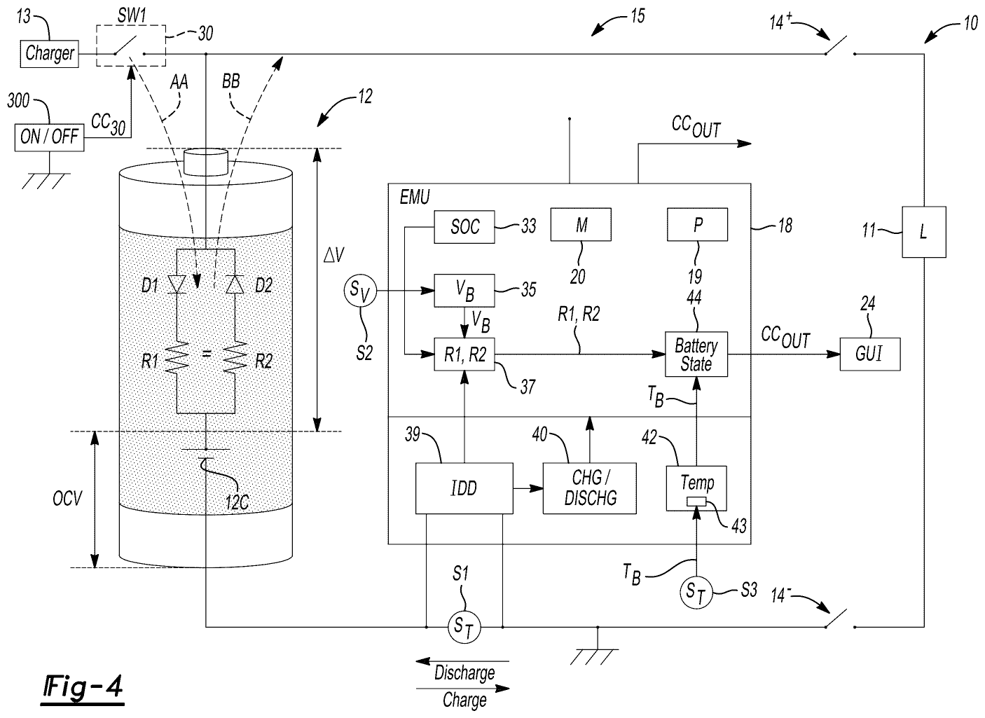

Referring to FIG. 4, the battery electric system 10 is illustrated schematically as the BMS 15 and the load 11. During a charging mode, the battery 12 is disconnected from the load 11 via the disconnect switches 14. A charging switch (SW1) 30 is commanded to close, e.g., by the EMU 18 or another charging controller, which connects the battery 12 to the battery charger 13. As appreciated in the art, the battery charger 13 may be connected to an offboard power supply (not shown). When the power supply is an AC outlet, the battery charger 13 includes an AC-to-DC converter to convert, filter, and output suitable DC voltage and current waveforms to the battery 12 for charging. A current sensor (S1), which is part of the sensor array 16 of FIG. 1 described above, may be used to detect the current flow direction and therefore help determine whether the battery 12 is in a charging mode or a discharging mode. The battery 12 is removed from the battery charger 13 when the battery 12 is in use (discharging mode), with removal of the battery 12 from the battery charger 13 automatically opening the charging switch 30.

In a possible implementation of the EMU 18, corresponding hardware and software modules or blocks may be implemented to perform the requisite processing functions of the method 50 (FIG. 7). A state of charge (SOC) block 33 may be used to determine the present SOC of the battery 12. The SOC block 33 may be implemented in various ways, such as but not limited to Coulomb counting. In such an approach, current flowing into and out of the battery 12 over time is tracked and integrated to determine the amount of transferred charge. Other approaches may include, e.g., machine learning, voltage and temperature-based lookup tables, temperature-specific OCV-SOC tables or curves, or other possible approaches.

The EMU 18 may also include a voltage measurement block 35. This feature may be implemented using a voltage sensor S2 of the sensor array 16 (FIG. 1), with the measured voltage periodically measured and communicated to the voltage measurement block 35 and stored in non-volatile portions of the memory 20. An internal resistance calculation block 37 may be used to calculate the charge-side resistance R1 and the discharge-side resistance R2 as part of the method 50 of FIG. 7 using data from blocks 33 and 35 as described below, along with measured current values from a current measurement block 39. The current sensor (S1) likewise measured and communicates a measured current value (IDD) to the internal resistance calculation block 37, and to a charge/discharge detection block 40 to determine when the battery 12 is charging or discharging. As noted above, this may be accomplished by detecting the current flow direction through the battery 12 which, due to the presence of diodes D1 and D2, may ordinarily in a single direction when the diodes D1 and D2 are properly configured and properly functioning.

The EMU 18 also considered battery temperature in evaluating the SOH of the battery 12. To that end, the EMU 18 is equipped with a temperature measurement block 42 which is in communication with a temperature sensor S3, e.g., a thermistor or thermocouple. The measured battery temperature (T_{B}) may be requested by, communicated to, and recorded by the temperature measurement block 42, possibly with assistance of an analog to digital converter (ADC) 43. The measured battery temperature (T_{B}) is then communicated to a battery state block 44 operable for determining an aging status of the battery 12, specifically its level of degradation. This function is performed using the reported charge-side and discharge-side resistances R1 and R2.

When the charge-side and discharge-side resistances R1 and R2 are high relative to thresholds as described below, alerts may be communicated by the EMU 18 via the output signals (CC_{OUT}), for instance to the GUI 24 or another external audio and/or visual device. Depending on the application, the alerts may entail audible alarms, indicator lights, text messages, or the like, which may include a request to discard or replace the battery 12. When the EMU 18 determines that failure of the battery 12 is imminent, the EMU 18 may take other preventive measures such as disconnecting the load 11 or preventing charging via the battery charger 13. Such actions may help prevent thermal damage to the surrounding environment or, for wearable versions of the battery electric system 10, to a user of the wearable device.

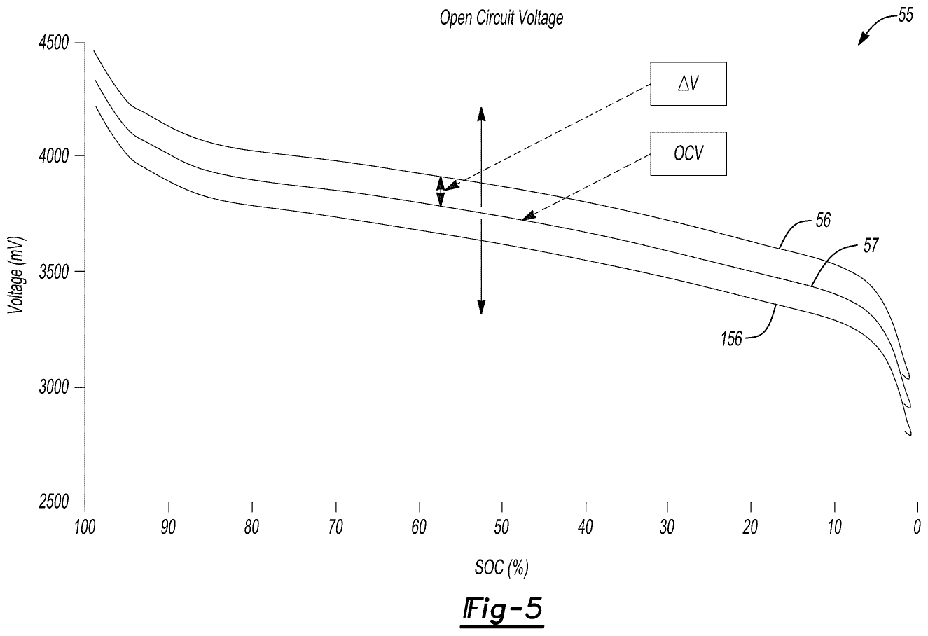

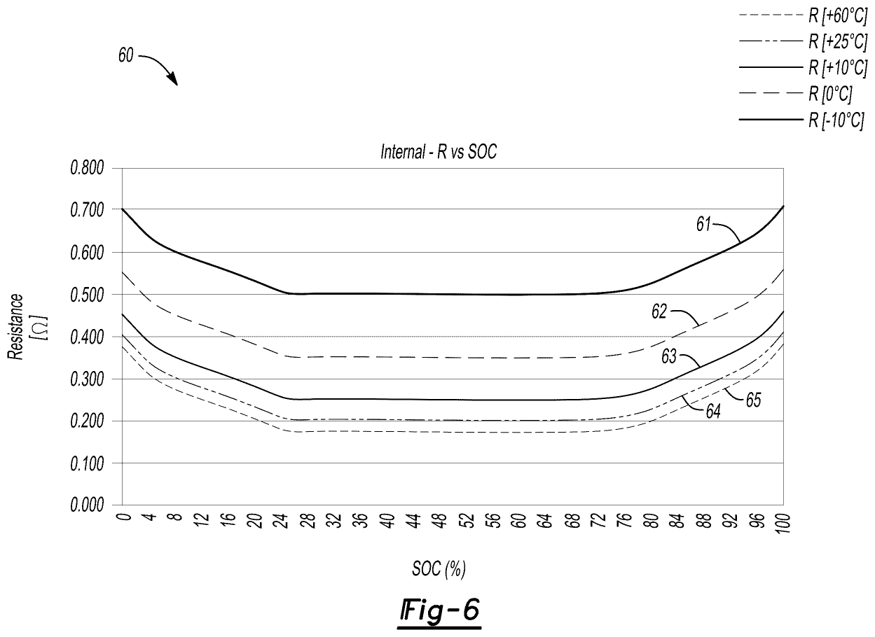

Relevant parameters of the battery 12 usable as part of the method 50 of FIG. 7 are explained with reference to FIGS. 5 and 6. FIG. 5 is a voltage plot 55 of battery voltage in millivolts (mV) versus the remaining capacity of the battery 12, with the remaining capacity expressed as an SOC percentage (%). Traces 56 and 156 represent the battery voltage during a charge mode and discharge mode of the battery 12, respectively, for a given temperature. Movement between traces 56 and 156 thus represents a voltage difference (ΔV) relative to a baseline, i.e., the open-circuit voltage (OCV). For a given temperature and capacity, therefore, the OCV acts as a stable reference from which the voltage difference (ΔV) may be determined as part of method 50. As appreciated in the art, the OCV, e.g., from a temperature-specific lookup table referenced or indexed by SOC and OCV, may be used to determine the voltage difference (ΔV) as shown. That is, ΔV is the difference in a measured battery voltage and the OCV, i.e., ΔV=Δ_{M}−OCV.

FIG. 6 illustrates via traces 60 that the internal resistance of the battery 12 increases in conjunction with state of charge (SOC) of the battery 12. This resistance, represented in ohms (Ω), is temperature-specific. For instance, trace 61 represents the resistance-to-SOC relationship for a representative battery 12 at −10°° C. Similarly, traces 62, 63, 64, and 65 represent the resistance-to-SOC relationship at 0° C., ⁺10° C., ⁺25° C., and ⁺60° C., respectively. The battery 12 at its lowest temperature in this example range therefore has the highest internal resistance at a given SOC. Thus, the present teachings may rely on one or more temperature-specific lookup tables including the SOC and OCV of the battery 12 as part of the operation of the EMU 18.

Referring now to FIG. 7, the method 50 is described as a sequence of steps or logic blocks, each of which may be embodied as computer-readable instructions. Such instructions may be recorded in memory 20 of the EMU 18 of FIG. 1, or in another accessible non-volatile, non-transitory memory location, and executed by the processor 19 to cause the EMU 18 to perform the described functions.

With brief reference to FIG. 1, execution of the instructions embodying the method 50 of FIG. 7 involves the cooperative use of the processor 19, the memory 20, and the sensor array 16 when evaluating the SOH of the battery 12. The functions of method 50 described in detail below are embodied computer-readable instructions and executed from the memory 20, for instance magnetic or optical media, CD-ROM, and/or solid-state/semiconductor memory (e.g., various types of RAM or ROM). The processor 19 may encompass one or more control modules, control units, microprocessor chips, Application Specific Integrated Circuit(s) (ASIC), Field-Programmable Gate Array(s) (FPGA(s)), electronic circuit(s), or central processing units. Associated memory component(s) of the memory 20 include non-transitory computer-readable storage devices such as read only memory, programmable read only memory, hard drive, etc. Non-transitory components of the memory 20 used herein are capable of storing machine-readable instructions in the form of one or more software or firmware programs or routines, combinational logic circuit(s), input/output circuit(s) and devices, signal conditioning and buffer circuitry and other components that can be accessed by one or more of the processors 19 to provide a described functionality.

In general, execution of such instructions from the memory 20 leads to generation of the measurement request signal (CCR) and its transmission to the sensor array 16. This in turn causes the processor 19, and thus the EMU 18, to receive a first set of battery parameters from the sensor array 16 during a charging event or mode of the battery 12. Additionally, the processor 19 is also caused to receive a second set of battery parameters from the sensor array 16 during a discharging mode of the battery 12. The first and second sets of battery parameters are communicated as part of the input signals (CC_{IN}) and include at least a voltage, a current, and a temperature of the battery 12.

Once the battery parameters have been communicated and received, the processor 19 calculates the charge-side resistance (R1) of the battery 12 during the charging mode. This occurs using the first set of battery parameters. The processor 19 also calculates the discharge-side resistance (R2) of the battery 12 during the discharging mode, which occurs using the second set of battery parameters. Thereafter, the processor 19 is caused to calculate aging or a degradation level of the battery 12 using the charge-side resistance (R1) and the discharge-side resistance (R2), and to thereafter perform a protective action in response to the degradation level exceeding a calibrated threshold.

An exemplary embodiment of the method 50 is illustrated in FIG. 7. Commencing with block B52 (“SOC, T”), the EMU 18 determines the SOC and temperature of the battery 12. SOC may be determined via the SOC block 33 of FIG. 3, e.g., using Coulomb counting, machine learning, voltage and temperature-based lookup tables, OCV-SOC curves, or other possible approaches as noted above. The temperature measurement block 42 described above with reference to FIG. 3 may be used to ascertain the temperature of the battery 12. The method 50 proceeds to block B54 after recording the SOC and corresponding temperature in non-volatile components of the memory 20.

Block B54 (“IDD-1”) entails measuring the battery current via the current sensor (S1) of FIG. 3. As with block B52, the measured value is recorded in non-volatile components of the memory 20. The method 50 then proceeds to block B56.

At block B56 (“Charge/Discharge?”), the EMU 18 determines whether the battery 12 is in a charging mode or a discharging mode. For instance, the EMU 18 may determine the current flow direction of the measured current from block B54 and other information, such as the state of the charging switch 30 of FIG. 3, to determine that the battery 12 is actively charging or discharging. The method 50 thereafter proceeds to block B58 when the EMU 18 determines that the battery 12 is in the charging mode, and to block B57 in the alternative when the EMU 18 determines that the battery 12 is in the discharging mode.

At block B57 (“Obtain OCV_{D} @ SOC_{X}”) of FIG. 7, the method 50 next determines the open circuit voltage (OCV_{C}) during the charging mode for the present SOC from block B52, i.e., SOC_{X}. As illustrated in the plot 55 of FIG. 5, OCV is specific to a given SOC. As appreciated in the art, OCV also increases with decreasing temperature (and vice versa). Therefore, block B58 is determined at the temperature measurement taken at block B52. The method 50 thereafter proceeds to block B59.

Block B58 (“Obtain OCV_{D} @ SOC_{X}”) is analogous to block B57, but is performed during a charging mode of the battery 12. Block B58 includes determining the open circuit voltage (OCV_{C}) during the charging mode for the present SOC from block B52. As illustrated in the plot 55 of FIG. 5, OCV is specific to a given SOC. As appreciated in the art, OCV also increases with decreasing temperature (and vice versa). Therefore, block B58 is determined at the temperature measurement taken at block B52. The method 50 thereafter proceeds to block B60.

Blocks B59 and B60 (“V2” and “V1”, respectively) include measuring the voltage of the battery 12 via the voltage sensor (S2) of FIG. 3. This value is then recorded in non-volatile components of the memory 20. The method 50 thereafter proceeds to block B61 (from block B59) or B62 (from block B60).

Block B61 (“R2 @ SOC_{X}”) is performed during a discharging mode of the battery 12 to calculate the discharge-side resistance (R2). As with block B62 described below, the method 50 proceeds to block B64 once the discharge-side resistance (R2) has been determined and recorded in non-volatile memory.

At block B62 (“R1 @ SOC_{X}”), the EMU 18 next calculates the charge-side resistance (R1) at the current SOC from block B52, i.e., the temperature-specific value SOC_{X}. Using ohmic resistance for simplicity, R1 may be set equal to v1/I, with V1 being the voltage measured in block B60 and/being the current IDD-1 measured in block B54. The method 50 proceeds to block B64 once the charge-side resistance (R1) has been determined and recorded in non-volatile memory.

Still referring to FIG. 7, block B64 (“Health Check”) includes performing a health check of the battery 12 via the EMU 18 using the recorded values of the charge-side resistance (R1) and discharge-side resistance (R2) from respective blocks B62 and B61 as described above. Block B64 may be implemented in various ways depending on the application. For instance, the instructions embodying the method 50 may be executable by the processor 19 of FIG. 1 to cause the EMU 18 to calculate a degradation level of the battery 12 or a comparable state of health (SOH) as a function of the resistances R1 and R2.

One possible approach is to evaluate the absolute difference between the charge-side resistance (R1) and the discharge-side resistance (R2). As noted above, these values are equal when the battery 12 is new, i.e., R1=R2 as shown in FIG. 3A. As shown in FIG. 3B, however, an aging/degrading battery 12 will experience an ever-increasing internal resistance disparity as the charge-side resistance (R1) increases faster than the discharge-side resistance (R2). Therefore, a possible strategy implementable by the EMU 18 is to compare the charge-side resistance (R1) to the discharge-side resistance (R2) to ascertain the magnitude of the difference. This magnitude of difference may be used as the degradation level.

Alternatively, the EMU 18 may track the values of the charge-side resistance (R1) and the discharge-side resistance (R2) over time, calculate the rate of change of each, and then compare the rates of change to each other to determine a difference or delta therebetween. In this instance, the instructions embodying method 50 are executable by the processor 19 to cause the EMU 18 to calculate a ratio of (i) a rate of increase of the charge-side resistance to (ii) a rate of increase of the discharge-side resistance. This calculated ratio may be used in one or more embodiments as the degradation level. The method 50 proceeds to block B66 when the EMU 18 has determined the degradation level of the battery 12.

At block B66 (“Battery SOH=OK?”), the EMU 18 next determines, using the above-described degradation level, whether the present operating state of the battery 12 is sufficiently healthy to continue its use without intervention. For example, a lookup table may be populated with escalating multiples of the discharge-side resistance (R2) or a value based thereon, with the EMU 18 comparing the charge-side resistance (R1) or values based thereon to the threshold(s).

Using a simplified example of this in which the degradation level is a magnitude of an absolute difference between R1 and R2, i.e., |R1−R2|, a lookup table in memory 20 of the EMU 18 could be populated with thresholds of, for example, 1.5R2, 2R2, 3R2, 4R2, etc. When using the rate of change of the charge-side resistance (R1) and the discharge-side resistance (R2), similar graduated thresholds may be employed, for instance

$$\frac{d}{dt} R 1 = 1.5 \frac{d}{dt} R 2 , 2 \frac{d}{dt} R 2 , 3 \frac{d}{dt} R 2 , 4 \frac{d}{dt} R 2 ,$$

etc. The method 50 proceeds to block B68 when the EMU 18 determines that the degradation level satisfies one of the programmed threshold conditions, i.e., that the battery 12 has aged or otherwise degraded to the point that invention is required. The method 50 returns in the alternative to block B52 when the EMU 18 determines that the battery 12 has not aged or deteriorated in a meaningful way.

At block B68 (“Preventive Action”), each threshold considered in block B66 is associated with a particular preventive control action. “Preventive” as contemplated herein refers to an action that notifies a user of the battery electric system 10 of FIG. 1 that the battery 12 is compromised in some way. When the battery 12 is only mildly degraded, the preventive action may take on a less urgent tone or mechanism, typically without the EMU 18 intervening in operation of the battery 12. However, as the degradation level becomes more significant, the EMU 18 may escalate the preventive action response in terms of its urgency, as well as possibly intervening in the control of the battery 12 itself.

Communication within the scope of block B68 may include transmitting an electronic alert signal to a remote device such as the GUI 14 of FIG. 1. Different levels of alerts or warning messages may be communicated this way. As thermal risks associated with the condition

$$R 1 = 1.5 R 2 ( or \frac{d}{dt} R 1 = 1.5 \frac{d}{dt} R 2 )$$

should be less than thermal risks associated with the condition

$$R 1 = 3 R 2 ( or \frac{d}{dt} R 1 = 3 \frac{d}{dt} R 2 ) ,$$

for example, an alert message communicated by the EMU 18 in response to the less urgent condition is itself less urgent in comparison to the alert message communicated in response to the more urgent condition.

Using an illustrative example, an SMS text message may be transmitted to the GUI 24 recommending replacement or service of the battery 12 within an extended timeframe or with unstated urgency, e.g., “Battery approaching end of useful life-service recommended.” If the battery electric system 10 of FIG. 1 is so equipped, a light or lamp may be lit with a corresponding color such as amber or yellow to visually alert users to the partially-degraded but still functional state of the battery 12. When the charge-side resistance becomes much greater than the discharge-side resistance, such as during the representative condition “R1=3R2”, the urgency of the alert/messaging may be likewise elevated. For instance, the above text example could be replaced with a more urgent phrasing such as “Battery condition poor-immediate service recommended.” The optional light may be illuminated in a universally understood color such as red in this example, and/or a light may be caused to pulsate or blink to elevate the alert status in a discernable manner. Audible warning tones may likewise be sounded to draw a user's attention to the possible imminent failure of the battery 12.

At some point, the EMU 18 may determine that continued use of the battery 12 would be potentially detrimental to the health and safety of the battery electric system 10 and possible users thereof. In this instance, the EMU 18 may be caused to execute the protective action by commanding the disconnect switch 14 (FIG. 1) to open and thereby disconnect the battery 12 from the load 11. Opening of the disconnect switch 14 effectively removes the battery 12 from a DC voltage bus connecting the battery 12 to the load 11, and therefore protects the load 11 from a discharge of power from the now-disconnected battery 12. Similarly, the EMU 18 may prevent the charging switch 30 from closing to prevent charging operations, for instance by transmitting an override or bypass signal to control logic of the battery charger 13 and/or charging switch 30. The battery 12 is thus isolated from the charging and discharging sides of the battery electric system 10.

Using the method 50 or embodiments thereof, lithium-ion and other high-energy batteries may be safely managed in a host of beneficial applications. The solutions presented herein enable early detection of potentially hazardous states of such batteries by separately evaluating internal resistance during charging and discharging, and by monitoring the changing relationship between such internal resistance values over time. Levels of degradation may be represented as numeric SOH values, for instance with an SOH of “1” corresponding to a perfectly healthy battery and an SOH of “0” corresponding to a fully degraded/inoperable battery. Values in between the normalized extremes of this exemplary range may correspond to progressively deteriorated states of the battery, e.g., the battery 12 described herein, with an SOH value closer to 0 being more degraded than those lying closer to an SOH value of 1. These and other benefits of the present teachings will be readily appreciated by those skilled in the art now having the benefit of the foregoing disclosure.

While several modes for carrying out the many aspects of the present teachings have been described in detail, those familiar with the art to which these teachings relate will recognize various alternative aspects for practicing the present teachings that are within the scope of the appended claims. The above description and accompanying drawings are illustrative and exemplary of the entire range of alternative embodiments that an ordinarily skilled artisan would recognize as implied by, structurally and/or functionally equivalent to, or otherwise rendered obvious based upon the included content, and not as limited solely to those explicitly depicted and/or described embodiments. Moreover, the present concepts expressly include combinations and sub-combinations of the described elements and features. The detailed description and the drawings are supportive and descriptive of the present teachings, with the scope of the present teachings defined solely by the claims.

What is claimed is:

1. A battery monitoring system (BMS) for a battery of a battery electric system, comprising:
a sensor array that is connectable to the battery;
a processor; and
a non-transitory computer-readable storage medium (“memory”), the memory including instructions executable by the processor to cause the processor to:
receive a voltage, a current, and a temperature of the battery from the sensor array during a charging mode of the battery and during a discharging mode of the battery;
calculate a charge-side resistance (R1) of the battery using the voltage, the current, and the temperature of the battery during the charging mode;
calculate a discharge-side resistance (R2) of the battery using the voltage, the current, and the temperature of the battery during the discharging mode; and
determine a degradation level of the battery using the charge-side resistance (R1) and the discharge-side resistance (R2).

2. The BMS of claim 1, wherein the instructions are executable by the processor to cause the processor to perform a preventive action of the battery in response to the degradation level of the battery exceeding a calibrated threshold.

3. The BMS of claim 1, wherein the instructions are executable by the processor to cause the processor to calculate the degradation level of the battery as a difference between the charge-side resistance and the discharge-side resistance.

4. The BMS of claim 1, wherein the instructions are executable by the processor to cause the processor to calculate a ratio of (i) a rate of increase of the charge-side resistance to (ii) a rate of increase of the discharge-side resistance, as a calculated ratio, and wherein the degradation level includes the calculated ratio.

5. The BMS of claim 1, wherein the instructions are executable by the processor to cause the processor to determine a state of charge (SOC) of the battery and an open-circuit voltage (OCV) of the battery at a given temperature of the battery, and wherein the instructions are executable by the processor to cause the processor to calculate the degradation level using the SOC and the OCV of the battery.

6. The BMS of claim 5, wherein the instructions are executable by the processor to cause the processor to access a temperature-specific lookup table including the SOC of the battery and the OCV of the battery.

7. The BMS of claim 1, wherein the instructions are executable by the processor to cause the processor to transmit an electronic alert signal to a remote device.

8. The BMS of claim 7, wherein the battery is connectable to a load via a disconnect switch within the battery electric system, and wherein the instructions are executable by the processor to cause the processor to command the disconnect switch to open and thereby disconnect the battery from the load.

9. A method for monitoring a battery in a battery electric system, the method comprising:
receiving, via a processor, a first set of battery parameters from a sensor array during a charging mode of the battery;
receiving, via the processor, a second set of battery parameters from the sensor array during a discharging mode of the battery, the first set of battery parameters and the second set of battery parameters including at least a voltage, a current, and a temperature of the battery;
calculating a charge-side resistance (R1) of the battery via the processor during the charging mode using the first set of battery parameters;
calculating a discharge-side resistance (R2) of the battery via the processor during the discharging mode using the second set of battery parameters; and
calculating a degradation level of the battery using the charge-side resistance (R1) and the discharge-side resistance (R2).

10. The method of claim 9, wherein calculating the degradation level of the battery includes calculating a difference between the charge-side resistance and the discharge-side resistance.

11. The method of claim 9, wherein calculating the degradation level of the battery includes calculating a ratio of (i) a rate of increase of the charge-side resistance to (ii) a rate of increase of the discharge-side resistance, as a calculated ratio, and wherein the degradation level includes the calculated ratio.

12. The method of claim 9, wherein calculating the degradation level of the battery includes:
determining a state of charge (SOC) of the battery at a given temperature of the battery; and
calculating the degradation level using the SOC.

13. The method of claim 12, further comprising:
accessing a lookup table indexed by the SOC of the battery and the temperature of the battery.

14. The method of claim 9, further comprising: performing a protective action of the battery in response to the degradation level exceeding a calibrated threshold, including transmitting an electronic alert signal to a remote device.

15. The method of claim 14, wherein the battery is connectable to a load via a disconnect switch within the battery electric system, and wherein performing the protective action includes commanding the disconnect switch to open and thereby disconnect the battery from the load.

16. A battery electric system, comprising:
a battery connectable to a battery charger during a charging mode;
a load connectable to the battery and energized thereby during a discharging mode;
a sensor array connected to the battery; and
an electronic monitoring unit (EMU) having a processor and a non-transitory computer-readable storage medium (“memory”), the memory including instructions executable by the processor to cause the EMU to:
transmit a measurement request signal to the sensor array;
receive, in response to the measurement request signal, a first set of battery parameters from the sensor array during the charging mode;
receive, in response to the measurement request signal, a second set of battery parameters from the sensor array during the discharging mode, the first set of battery parameters and the second set of battery parameters including at least a voltage, a current, and a temperature of the battery;
calculate a charge-side resistance (R1) of the battery during the charging mode using the first set of battery parameters;
calculate a discharge-side resistance (R2) of the battery during the discharging mode using the second set of battery parameters;
calculate a degradation level of the battery using the charge-side resistance (R1) and the discharge-side resistance (R2); and
perform a protective action of the battery in response to the degradation level exceeding a calibrated threshold.

17. The battery electric system of claim 16, wherein the instructions are executable by the processor to cause the EMU to calculate the degradation level of the battery as a difference between the charge-side resistance and the discharge-side resistance.

18. The battery electric system of claim 16, wherein the instructions are executable by the processor to cause the EMU to calculate a ratio of (i) a rate of increase of the charge-side resistance to (ii) a rate of increase of the discharge-side resistance, as a calculated ratio, and wherein the degradation level includes the calculated ratio.

19. The battery electric system of claim 16, wherein the EMU includes a state of charge (SOC) calculation block operable for determining an SOC and an open-circuit voltage (OCV) of the battery at a given temperature of the battery, and wherein the instructions are executable by the processor to cause the EMU to calculate the degradation level using the SOC and the OCV of the battery,, wherein the instructions are executable by the processor to cause the EMU to access a temperature-specific lookup table indexed by the SOC and the OCV of the battery.

20. The battery electric system of claim 16, wherein the battery is connectable to a load via a disconnect switch, and wherein the instructions are executable by the processor to cause the EMU to execute the protective action by commanding the disconnect switch to open and thereby disconnect the battery from the load.
